(19) United States
(12) Patent Application Publication
(10) Pub. No.: US 2025/0003051 A1
(43) Pub. Date: Jan. 2, 2025

(54) MASK ASSEMBLY AND METHOD OF MANUFACTURING DISPLAY PANEL

(71) Applicant: Samsung Display Co., Ltd., Yongin-si (KR)

(72) Inventors: SANGHOON KIM, Yongin-si (KR); YEONJU KANG, Yongin-si (KR); Yuri LEE, Yongin-si (KR)

(73) Assignee: Samsung Display Co., Ltd., Yongin-si (KR)

(21) Appl. No.: 18/753,433

(22) Filed: Jun. 25, 2024

(30) Foreign Application Priority Data
Jun. 27, 2023 (KR) 10-2023-0082316

(51) Int. Cl. C23C 14/04; H10K 71/16

(52) U.S. Cl. CPC C23C 14/042; H10K 71/166

(57) ABSTRACT

A mask assembly includes a frame including a frame opening, a first stick disposed on the frame, the first stick overlapping the frame opening and extending in a first direction in a plan view, and a mask disposed on the first stick. The mask includes active areas and an inactive area, each of the active areas includes a first active area including holes, a second active area including first grooves, and a third active area including second grooves, the third active area overlaps the second active area in a second direction intersecting the first direction, and the first stick overlaps the third active area in the plan view.

### CROSS-REFERENCE TO RELATED APPLICATION(S)

This application claims priority to and benefits of Korean Patent Application No. 10-2023-0082316, under 35 U.S.C. §119 filed on Jun. 27, 2023 in the Korean Intellectual Property Office, the entire contents of which are incorporated herein by reference.

### BACKGROUND

### 1. Technical Field

The disclosure relates to a mask assembly and a method of manufacturing a display panel. For example, the disclosure relates to a mask assembly including a mask in which a bending phenomenon of the mask occurring while being tensioned is improved and a method of manufacturing a display panel.

### 2. Description of the Related Art

A display device may be manufactured through various processes. As an example, a deposition process may be used to manufacture the display device. A fine metal mask (FMM) that is tightly attached to a substrate for the deposition of an organic material may be used in the deposition process for the display device. A cell unit mask may be used in the deposition process for the display device.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a mask assembly including a mask in which a bending phenomenon occurring when being tensioned is improved.

The disclosure provides a method of manufacturing a display panel using the mask assembly.

Embodiments provide a mask assembly that may include a frame including a frame opening; a first stick disposed on the frame, overlapping the frame opening in a plan view, and extending in a first direction; and a mask disposed on the first stick. The mask may include a plurality of active areas and an inactive area, each of the plurality of active areas may include a first active area including a plurality of holes; a second active area including a plurality of first grooves; and a third active area including a plurality of second grooves, the third active area overlaps the second active area in a second direction intersecting the first direction, and the first stick overlaps the third active area in the plan view.

A width in a third direction intersecting the first direction and the second direction of each of the plurality of holes may be greater than a width in the third direction of each of the plurality of first grooves and the plurality of second grooves.

A width in the third direction of each of the plurality of first grooves and the plurality of second grooves may be equal to or greater than about 40% and equal to or less than about 60% of the width in the third direction of each of the plurality of holes.

Each of the plurality of active areas may have a substantially rectangular shape, and the plurality of active areas may be disposed in the first direction.

Each of the plurality of active areas may include a first side parallel to the first direction and a second side parallel to the second direction, and the first side may have a length less than a length of the second side.

Each of the plurality of active areas may include a first side parallel to the first direction and a second side parallel to the second direction, and the first side may have a length greater than a length of the second side.

Each of the plurality of active areas may include a first side parallel to the first direction, a third side parallel to the first direction and opposite to the first side, a second side parallel to the second direction, and a fourth side parallel to the second direction and opposite to the second side, the second active area may be disposed adjacent to the first side, and the third active area may be disposed adjacent to the third side.

The first active area may include a first-first active area including the first side and a first-second active area including the third side, and the first stick may overlap the first-second active area in the plan view.

The first stick may not overlap the second active area in the plan view.

The mask assembly may further include a second stick disposed between the frame and the mask and extending in the second direction.

Each of the masks may include a plurality of masks, the first stick may include a plurality of first sticks, and the second stick may include a plurality f second sticks, the plurality of second sticks may be disposed in the first direction, the plurality of first sticks may be disposed in the second direction, and the plurality of masks may be disposed in the second direction.

A width in the first direction of the second stick may be less than a width between two adjacent active areas among the plurality of active areas.

A width in the second direction of the first stick may be greater than a width in the second direction of the third active area.

The mask may include a magnetic material, and the first stick and the second stick may include a non-magnetic material.

The mask may include invar, and the first stick and the second stick may include aluminum.

Embodiments provide a method of manufacturing a display panel. The method may include providing a substrate; placing a mask assembly on the substrate; and depositing an organic material on the mask to form a pattern. The mask assembly may include a frame including a frame opening; a first stick disposed on the frame, overlapping the frame opening in a plan view, and extending in a first direction; and a mask disposed on the first stick. The mask may include a plurality of active areas and an inactive area, each of the plurality of active areas may include a first active area including a plurality of holes, a second active area including a plurality of first grooves, and a third active area including a plurality of second grooves, the third active area may overlap the second active area in a second direction intersecting the first direction, and the first stick may overlap the third active area in the plan view.

The organic material may include a light emitting material, and the pattern may include a light emitting layer.

A width in a third direction intersecting the first direction and the second direction of each of the plurality of holes may be greater than a width in the third direction of each of the plurality of first grooves and the plurality of second grooves.

A width in the first direction of the mask may be greater than a width in the first direction of the frame opening.

The mask may include a welding portion that may not overlap the frame opening in the plan view, and the welding portion may be welded to the frame.

According to the above, the mask assembly may include the second active area and the third active area, which may overlap each other in the second direction, and thus, the mask may be prevented from being bent or twisted when being tensioned.

According to the above, in case that the display panel is manufactured, the mask assembly that may include the second active area and the third active area overlapping the second active area in the second direction is used to prevent the mask from being bent or twisted, and thus, a durability of a deposition device is improved while providing stable productivity.

### BRIEF DESCRIPTION OF THE DRAWINGS

The above and other advantages of the disclosure will become readily apparent by reference to the following detailed description when considered in conjunction with the accompanying drawings wherein:

FIG. 1 is a schematic perspective view of a mask assembly according to an embodiment;

FIG. 2 is an exploded perspective view of the mask assembly shown in FIG. 1;

FIG. 3 is an enlarged view of an area AA′ shown in FIG. 2;

FIG. 4 is a schematic cross-sectional view taken along line I-I′ shown in FIG. 3;

FIG. 5 is a flowchart illustrating a method of manufacturing a display panel according to an embodiment;

FIG. 6 is a schematic cross-sectional view illustrating a process of the manufacturing method of the display panel according to an embodiment;

FIG. 7 is a schematic plan view of a pattern formed through a manufacturing method of a display panel according to an embodiment;

FIG. 8 is a schematic perspective view of an electronic device including a display panel according to an embodiment;

FIG. 9 is an exploded perspective view of an electronic device including a display panel according to an embodiment;

FIG. 10 is a schematic cross-sectional view of a display panel according to an embodiment;

FIG. 11 is a schematic plan view showing a variation in shape of a mask according to a comparative example; and

FIG. 12 is a schematic plan view showing a variation in shape of a mask according to an embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the disclosure, it will be understood that when an element (or area, layer, or portion) is referred to as being “on”, “connected to” or “coupled to” another element or layer, it can be directly on, connected or coupled to the other element or layer or intervening elements or layers may be present.

It will be understood that the terms “connected to” or “coupled to” may include a physical or electrical connection or coupling.

Like numerals refer to like elements throughout. In the drawings, the thickness, ratio, and dimension of components are exaggerated for effective description of the technical content.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.”

It will be understood that, although the terms first, second, etc. may be used herein to describe various elements, these elements should not be limited by these terms. These terms are only used to distinguish one element from another element. Thus, a first element discussed below could be termed a second element without departing from the teachings of the disclosure.

As used herein, the singular forms, “a”, “an” and “the” are intended to include the plural forms as well, unless the context clearly indicates otherwise.

Spatially relative terms, such as “beneath”, “below”, “lower”, “above”, “upper” and the like, may be used herein for ease of description to describe one element or feature's relationship to another elements or features as shown in the figures.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be further understood that the terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

In the disclosure, a direction intersecting a first direction DR1 is referred to as a second direction DR2. A direction substantially perpendicular to a plane defined by the first and second directions DR1 and DR2 is referred to as a third direction DR3.

In the disclosure, the expression “when viewed in a plane” or “in a plan view” means a state of being viewed in the third direction DR3. In the disclosure, the expression “an organic material is sprayed” or “an organic material transmits” means that the organic material is sprayed or transmits in a direction from a mask MK to a frame FR.

Hereinafter, embodiments will be described with reference to accompanying drawings.

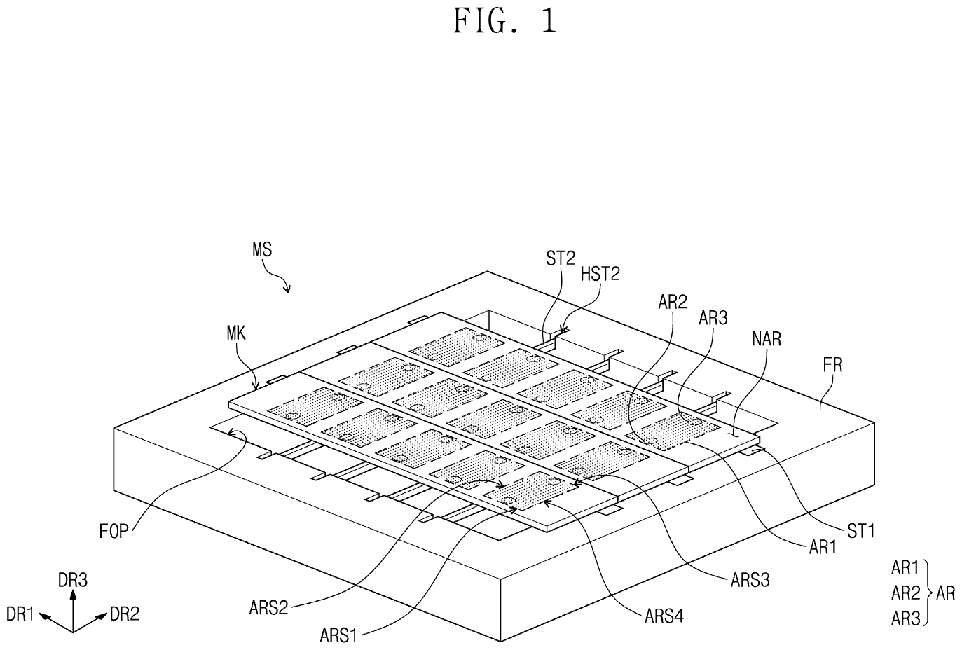

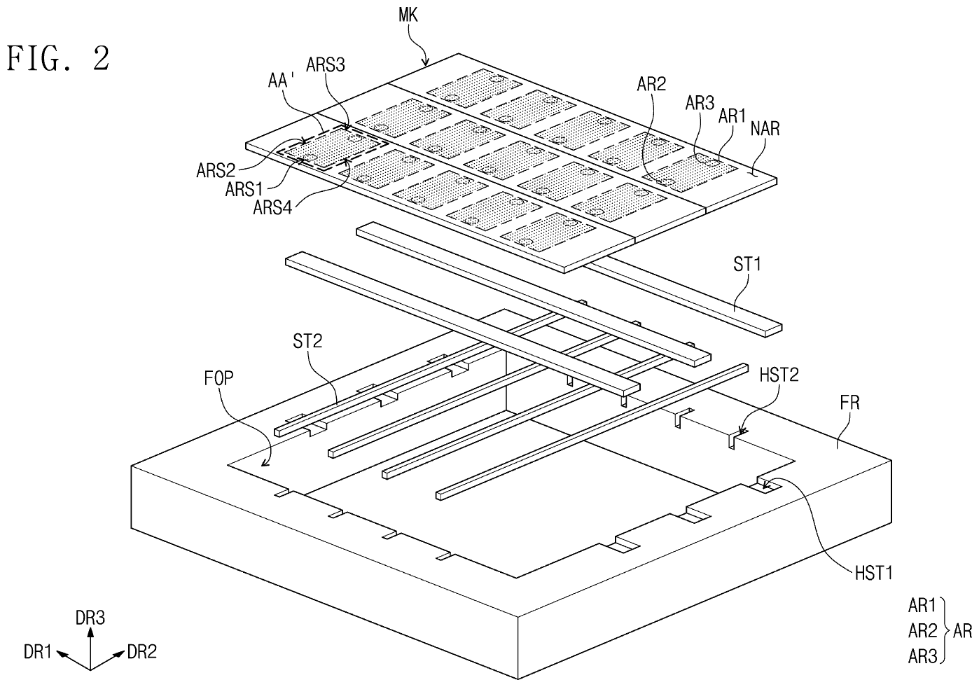

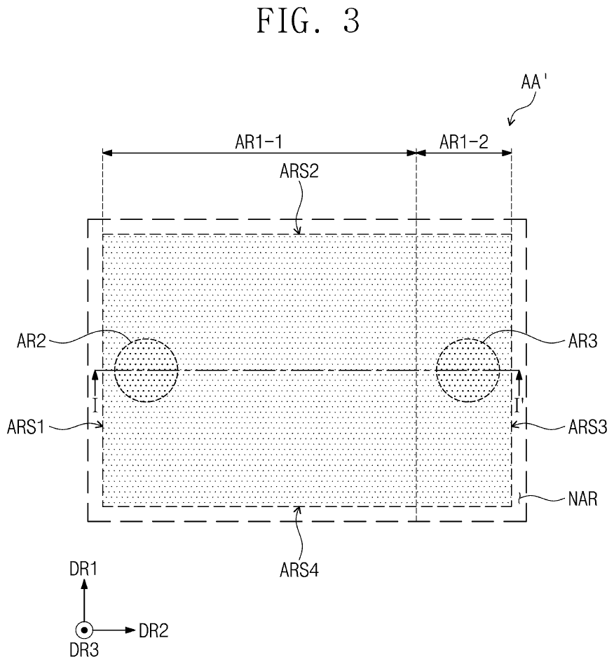

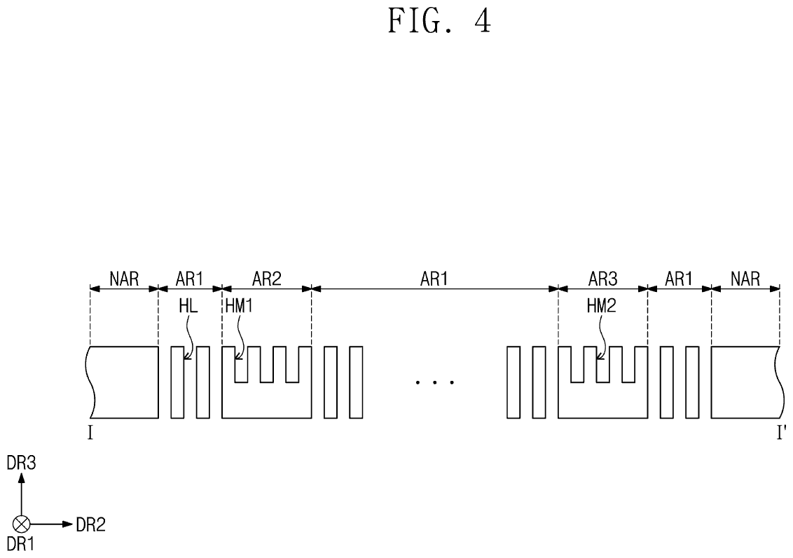

FIG. 1 is a schematic perspective view of a mask assembly MS according to an embodiment. FIG. 2 is an exploded perspective view of the mask assembly MS shown in FIG. 1. FIG. 3 is an enlarged view of an area AA′ shown in FIG. 2. FIG. 4 is a schematic cross-sectional view taken along line I-I′ shown in FIG. 3.

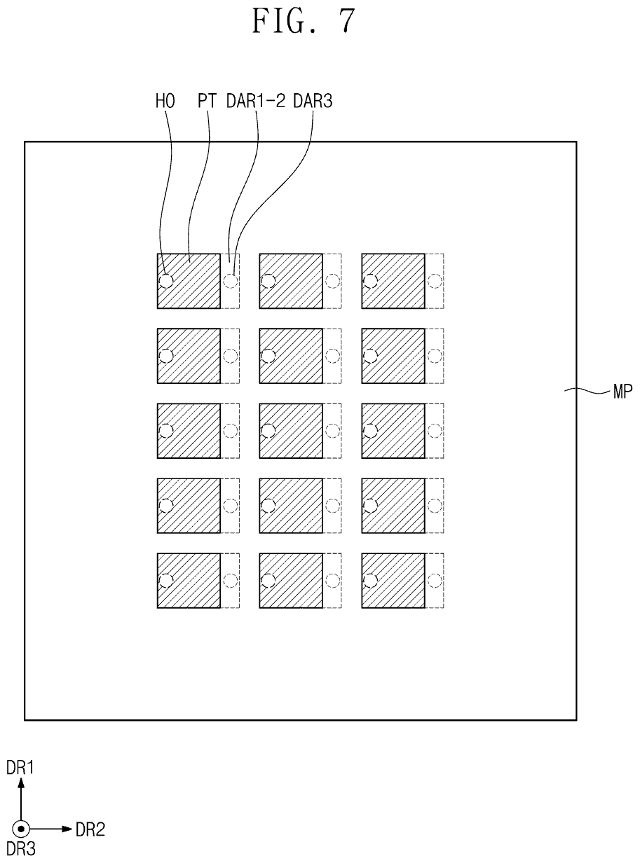

Referring to FIGS. 1 and 2, the mask assembly MS may include a frame FR through which a frame opening FOP is defined, a first stick ST1 disposed on the frame FR, overlapping the frame opening FOP when viewed in a plane, and extending in the first direction DR1, and a mask MK disposed on the first stick ST1. The frame opening FOP may be formed to completely penetrate the frame FR. The frame opening FOP may have a quadrangular shape. The frame FR may include a plurality of first stick grooves HST1 to which the first stick ST1 is coupled. The frame FR and the first stick ST1 may be coupled with or connected with each other by a welding method. The frame opening FOP may be used as a path through which an organic material transmits to form a pattern PT (refer to FIG. 7).

The frame FR may include the first stick groove HST1 and a second stick groove HST2. The first stick groove HST1 may be a space in which the first stick ST1 is fixed to the frame FR. The second stick groove HST2 may be a space in which a second stick ST2 is fixed to the frame FR. A width in the third direction DR3 of the first stick groove HST1 may be greater than a width in the third direction DR3 of the first stick ST1. A width in the third direction DR3 of the second stick groove HST2 may be greater than a width in the third direction DR3 of the second stick ST2. A width in the second direction DR2 of the first stick groove HST1 may be substantially the same as a width in the second direction DR2 of the first stick ST1. A width in the first direction DR1 of the second stick groove HST2 may be substantially the same as a width in the first direction DR1 of the second stick ST2. The first stick groove HST1 and the second stick groove HST2 may be defined adjacent to the frame opening FOP. Each of the first stick groove HST1 and the second stick groove HST2 of the frame FR may be provided in plural.

The first stick ST1 may have a quadrangular shape with long sides and short sides. The long sides of the first stick ST1 may be substantially parallel to the first direction DR1. The first stick ST1 may be coupled with or connected with the first stick groove HST1. The first stick ST1 may be coupled with or connected with the first stick groove HST1 by the welding method.

The mask MK may be disposed directly on the first stick ST1. An area where the first stick ST1 overlaps the mask MK when viewed in the plane may be an area through which no organic material transmits. The mask MK may be a fine metal mask. The mask MK may include a magnetic material. As an example, the mask MK may include invar, however, this is an example.

The mask MK may include a plurality of active areas AR and an inactive area NAR.

The inactive area NAR may correspond to a remaining area of the frame FR except the active area AR. The inactive area NAR may surround the active area AR.

The mask assembly MS may further include the second stick ST2.

The second stick ST2 may have a quadrangular shape with long sides and short sides. The long sides of the second stick ST2 may be substantially parallel to the second direction DR2. The second stick ST2 may be coupled with or connected with the second stick groove HST2. The second stick ST2 may be coupled with or connected with the second stick groove HST2 by the welding method.

The first stick ST1 may be disposed between the second stick ST2 and the mask MK. The first stick ST1 may be disposed directly on the second stick ST2. The second stick ST2 may serve as a supporter to prevent the mask MK from falling down and being separated. However, an arrangement relation between the first stick ST1 and the second stick ST2 should not be limited thereto or thereby, and according to an embodiment, the second stick ST2 may be disposed between the first stick ST1 and the mask MK.

The first stick ST1 and the second stick ST2 may include a non-magnetic material. As an example, the first stick ST1 and the second stick ST2 may include aluminum, however, this is an example.

According to an embodiment, each of the mask MK, the first stick ST1, and the second stick ST2 may be provided in plural. The second sticks ST2 may be disposed spaced apart from each other in the first direction DR1. The first sticks ST1 may be disposed spaced apart from each other in the second direction DR2. The masks MK may be disposed in the second direction DR2. A width in the first direction DR1 of the second stick ST2 may be smaller than a width between two arbitrary active areas AR adjacent to each other among the active areas AR.

Referring to FIGS. 1, 3, and 4, each of the active areas AR may include a first active area AR1 in which a plurality of holes HL is defined, a second active area AR2 in which a plurality of first grooves HM1 is defined, and a third active area AR3 in which a plurality of second grooves HM2 is defined. The third active area AR3 may overlap the second active area AR2 in the second direction DR2. The first stick ST1 may overlap the third active area AR3 when viewed in the plane.

Each of the active areas AR may have a rectangular shape. Each of the active areas AR may include a first side ARS1 parallel to the first direction DR1, a third side ARS3 parallel to the first direction DR1 and opposite to the first side ARS1, a second side ARS2 parallel to the second direction DR2, and a fourth side ARS4 parallel to the second direction DR2 and opposite to the second side ARS2. Each of the first side ARS1, the second side ARS2, the third side ARS3, and the fourth side ARS4 may correspond to one side or a side of the rectangular shape. The first side ARS1 may be substantially perpendicular to the second side ARS2, and the third side ARS3 may be substantially perpendicular to the fourth side ARS4. A length of the first side ARS1 may be substantially the same as a length of the third side ARS3, and a length of the second side ARS2 may be substantially the same as a length of the fourth side ARS4. The length of the first side ARS1 may be smaller than the length of the second side ARS2. The first side ARS1 has a length greater than a length of the second side ARS2.

The third active area AR3 may overlap the second active area AR2 in the second direction DR2. The second active area AR2 may be adjacent to the first side ARS1, and the third active area AR3 may be adjacent to the third side ARS3. Each of the second active area AR2 and the third active area AR3 may have a circular shape. The second active area AR2 and the third active area AR3 may have substantially the same size. In the case where each of the second active area AR2 and the third active area AR3 has the circular shape, a width between a center point of the second active area AR2 and the first side ARS1 in the second direction DR2 may be substantially the same as a width between a center point of the third active area AR3 and the third side ARS3 in the second direction DR2. The third active area AR3 may be symmetrical with the second active area AR2 and may improve a bending phenomenon of the mask MK in case that the mask MK is tensioned.

The first stick ST1 may overlap the third active area AR3 when viewed in the plane. The width in the second direction DR2 of the first stick ST1 may be greater than the width in the second direction DR2 of the third active area AR3.

The first active area AR1 may include a first-first active area AR1-1 including the first side ARS1 and a first-second active area AR1-2 including the third side ARS3. The first-first active area AR1-1 may surround the second active area AR2. The first-second active area AR1-2 may surround the third active area AR3. A width in the first direction DR1 of the first-first active area AR1-1 may be substantially the same as a length of the first side ARS1. A width in the first direction DR1 of the first-second active area AR1-2 may be substantially the same as a length of the third side ARS3.

The first-second active area AR1-2 may overlap the first stick ST1 when viewed in the plane. A width in the second direction DR2 of the first-second active area AR1-2 may be smaller than the width in the second direction DR2 of the first stick ST1. Since the first-second active area AR1-2 and the third active area AR3 overlap the first stick ST1 when viewed in the plane, the organic material sprayed to the first-second active area AR1-2 and the third active area AR3 may not pass through the mask MK in the process of depositing the organic material using the mask assembly MS. For example, similar to the inactive area NAR, the first-second active area AR1-2 and the third active area AR3 may be areas through which no organic material transmits in the deposition process.

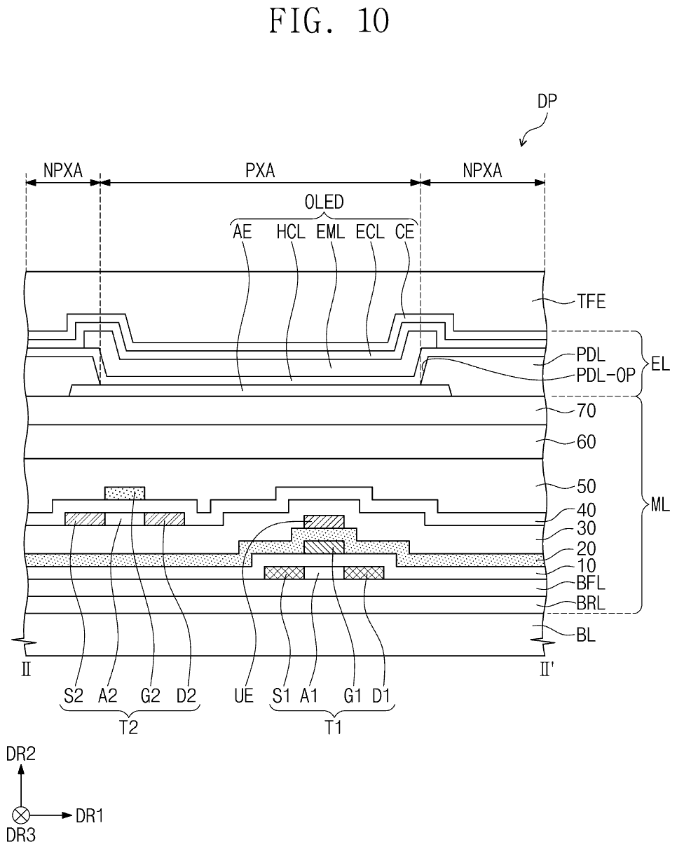

Referring to FIGS. 1 and 4, the organic material may pass through the active area AR. The active area AR may include the first active area AR1. The first active area AR1 may include the holes HL. The holes HL may be uniformly distributed in the first active area AR1. The holes HL may be formed to completely penetrate the mask MK. The organic material may pass through the holes HL to form the pattern PT (refer to FIG. 7). Each of the holes HL may form a pattern corresponding to each light emitting layer EML (refer to FIG. 10) of the display panel DP. A width in the third direction DR3 of the hole HL may be substantially the same as a width in the third direction DR3 of the mask MK.

Each of the holes HL may have a diameter greater than a diameter of the organic material. The holes HL may have diameters different from each other. As an example, the diameter of the holes HL may be equal to or greater than about 0.01 μm and equal to or smaller than about 5 μm, however, this is an example.

The active area AR may include the second active area AR2 including the first grooves HM1 and the third active area AR3 including the second grooves HM2.

The first grooves HM1 and the second grooves HM2 may be uniformly distributed in the second active area AR2 and the third active area AR3, respectively. The first groove HM1 and the second groove HM2 may be a recess defined by removing a portion of the mask MK. The expression “The first groove HM1 and the second groove HM2 are defined by removing the portion of the mask MK.” may mean that concave portions are formed in an upper surface of the mask MK. Different from the holes HL, the organic material may not pass through the first groove HM1 and the second groove HM2. The organic material may not pass through the second active area AR2 including the first grooves HM1 and the third active area AR3 including the second grooves HM2. The third active area AR3 and the second active area AR2 may be symmetrical with each other and may allow the tensile force to be symmetrically applied to the mask MK in case that the mask MK is tensioned to prevent the mask MK from being bent. Since the active area AR is formed bilaterally symmetrically to prevent the occurrence of bending of the mask MK, the occurrence of the bending of the mask MK may be improved in case that the mask MK may include the first-second active area AR1-2 surrounding the third active area AR3. The pattern PT (refer to FIG. 7), which is formed by the organic material deposited on a mother substrate MP (refer to FIG. 7) after passing through the hole HL, may be formed to correspond to the first-first active area AR1-1, the first-second active area AR1-2 may be defined to overlap the first stick ST1, and thus, the pattern PT (refer to FIG. 7) may not be formed in the first-second active area AR1-2. For example, in case that the organic material is sprayed in a state where the first-second active area AR1-2 is disposed on the first stick ST1, the organic material may pass through the holes HL included in the first-second active area AR1-2 but may not pass through the first stick ST1.

A width in the third direction DR3 of the hole HL may be greater than the width in the third direction DR3 of the first groove HM1 and the second groove HM2. As an example, the width in the third direction DR3 of the first groove HM1 and the second groove HM2 may be equal to or greater than about 40% or equal to or smaller than about 60% of the width in the third direction DR3 of the hole HL, however, this is an example.

The inactive area NAR may not include the hole HL or the grooves HM1 and HM2. The inactive area NAR may not transmit the organic material.

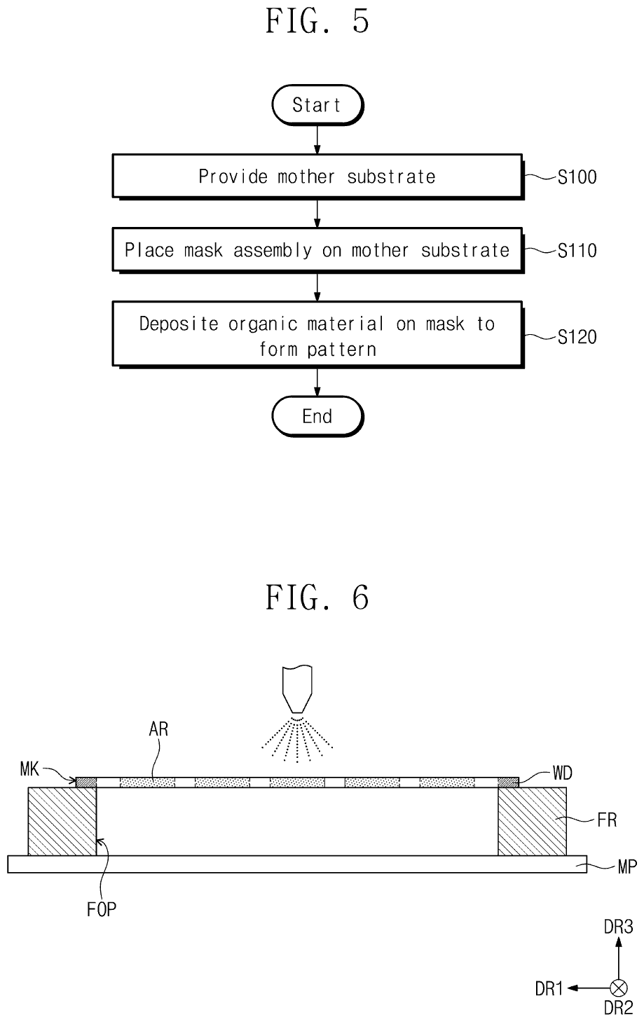

FIG. 5 is a flowchart illustrating a method of manufacturing the display panel according to an embodiment.

FIG. 6 is a schematic cross-sectional view illustrating a process of the manufacturing method of the display panel according to an embodiment.

FIG. 7 is a schematic plan view of the pattern formed through the manufacturing method of the display panel according to an embodiment.

Referring to FIGS. 5, 6, and 7, the manufacturing method of the display panel DP may include providing the mother substrate MP (S100), placing the mask assembly MS on the mother substrate MP (S110), and depositing the organic material on the mask MK to form the pattern PT (S120).

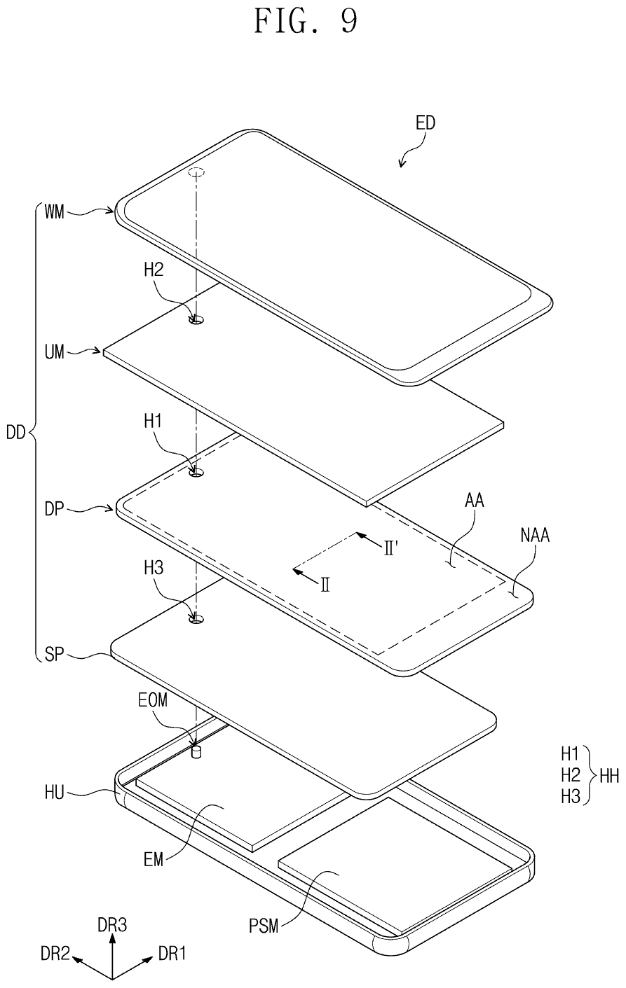

The manufacturing method of the display panel DP (refer to FIG. 9) may include the providing of the mother substrate MP (S100). The mother substrate MP may be a substrate on which the organic material is deposited. The frame FR may be disposed directly on the mother substrate MP.

The manufacturing method of the display panel DP may include the placing of the mask assembly MS on the mother substrate MP (S110). Referring to FIGS. 6 and 1, the mask assembly MS may include the first stick ST1. The mask assembly MS may include the frame FR through which the frame opening FOP is defined, the first stick ST1 disposed on the frame FR, overlapping the frame opening FOP when viewed in the plane, and extending in the first direction DR1, and the mask MK disposed on the first stick ST1. The mask MK may include the active areas AR and the inactive area NAR, and each of the active areas AR may include the first active area AR1 including the holes HL, the second active area AR2 including the first grooves HM1, and the third active area AR3 including the second grooves HM2. The third active area AR3 may overlap the second active area AR2 when viewed in the second direction DR2 intersecting the first direction DR1, and the first stick ST1 may overlap the third active area AR3 when viewed in the plane.

The manufacturing method of the display panel DP (refer to FIG. 9) may include the depositing of the organic material on the mask MK to form the pattern PT (S120).

The organic material may be sprayed in a direction opposite to the third direction DR3 from the above of the mask MK. The sprayed organic material may be deposited on the mother substrate MP after passing through the holes HL. The organic material deposited on the mother substrate MP may include a light emitting material. The pattern PT formed by depositing the organic material may include the light emitting layer EML (refer to FIG. 10). A camera hole HO may correspond to the second active area AR2 of the mask. The camera hole HO may be an area where the organic material is not deposited. The pattern PT may correspond to an area where the organic material is deposited. The pattern PT may be formed by the organic material that is sprayed, passed through the holes HL included in the first-first active area AR1-1, and deposited onto the mother substrate MP. The camera hole HO may be an area where the organic material is not deposited on the mother substrate MP in the process of spaying the organic material since the organic material does not pass through the first groove HM1 of the second active area AR2. A first-second dummy area DAR1-2 may correspond to the first-second active area AR1-2, and a third dummy area DAR3 may correspond to the third active area AR3. The first-second dummy area DAR1-2 may be an area where the organic material is blocked by the first stick ST1 disposed under (or below) the mask MK and is not deposited on the mother substrate MP. The third dummy area DAR3 may be an area where the organic material sprayed toward the third active area AR3 is blocked by the second grooves HM2 of the third active area AR3 and is not deposited on the mother substrate MP.

In the manufacturing method of the display panel DP (refer to FIG. 9), a width in the first direction DR1 of the mask MK may be greater than a width in the first direction DR1 of the frame opening FOP. The mask MK may include a welding portion WD where the mask MK does not overlap the frame opening FOP when viewed in the plane. The welding portion WD may allow the frame FR and the mask MK to be welded together. The welding portion WD may perform a function that prevents the mask MK from departing from the frame FR. The welding portion WD may not overlap the frame opening FOP when viewed in the plane and may overlap the frame FR.

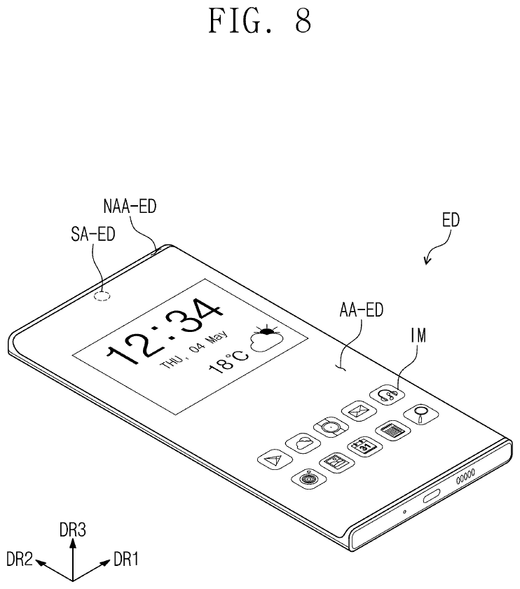

FIG. 8 is a schematic perspective view of an electronic device ED including the display panel according to an embodiment. FIG. 9 is an exploded perspective view of the electronic device ED including the display panel according to an embodiment. FIG. 10 is a schematic cross-sectional view of the display panel DP according to an embodiment.

Referring to FIGS. 8 and 9, the electronic device ED may be a device that is activated in response to electrical signals. The electronic device ED may be applied to a mobile phone, a tablet computer, a car navigation unit, a game unit, or a wearable device, however, it should not be limited thereto or thereby. FIG. 8 shows the mobile phone as a representative example of the electronic device ED including the display panel DP.

The electronic device ED may display an image IM through an active area AA-ED. The active area AA-ED may include a plane defined by the first direction DR1 and the second direction DR2. The active area AA-ED may further include a curved surface bent from at least one side or a side of the plane defined by the first direction DR1 and the second direction DR2. The electronic device ED shown in FIG. 8 may include two curved surfaces respectively bent from both of opposite sides of the plane defined by the first direction DR1 and the second direction DR2. However, the shape of the active area AA-ED should not be limited thereto or thereby. For example, the active area AA-ED may include only the plane, or the active area AA-ED may include curved surfaces respectively bent from at least two sides, for example, the active area AA-ED may include four curved surfaces respectively bent from four sides of the plane.

The electronic device ED may include a sensing area SA-ED defined therein. FIG. 8 shows one sensing area SA-ED, however, the number of the sensing areas SA-ED should not be limited thereto or thereby, and two or more sensing areas SA-ED may be defined. The sensing area SA-ED may be defined in the active area AA-ED and may be a portion of the active area AA-ED.

The electronic device ED may include the active area AA-ED and a peripheral area NAA-ED adjacent to the active area AA-ED. The active area AA-ED may correspond to a display area AA of the display panel DP, and the peripheral area NAA-ED may correspond to a non-display area NAA of the display panel DP.

The peripheral area NAA-ED may be an area to block an optical signal and may be disposed outside the active area AA-ED to surround the active area AA-ED. According to an embodiment, the peripheral area NAA-ED may be defined in a side surface of the electronic device ED rather than a front surface of the electronic device ED. The electronic device ED may include at least one side surface or a side surface that is bent, and the peripheral area NAA-ED may be defined in the bent side surface.

The electronic device ED may include a display device DD, a housing HU, and an electro-optical module EOM. The display device DD may include a window WM, an upper member UM, the display panel DP, and a lower member SP.

The display device DD may include the window WM disposed on the display panel DP. The window WM may provide an exterior of the electronic device ED. The window WM may cover a front surface of the display panel DP and may protect the display panel DP from external impacts and scratches. The window WM may be attached to the upper member UM by an adhesive layer.

The window WM may include an optically transparent insulating material. As an example, the window WM may include a cover glass or a synthetic resin film as its cover member. The window WM may have a single-layer or multi-layer structure. For example, the window WM may have a single-layer structure of a cover glass, may have a structure in which a plurality of plastic films is coupled to each other by an adhesive, or may have a structure in which a cover glass and a plastic film are coupled to each other by an adhesive. The window WM may further include a functional layer, such as an anti-fingerprint layer, a phase control layer, a hard coating layer, etc., disposed on a transparent base.

In the display device DD, the upper member UM may be disposed under (or below) the window WM and on the display module DM. The upper member UM may include an anti-reflective layer and an input sensing sensor. The anti-reflective layer may reduce a reflectance of the display device DD with respect to an external light. The input sensing sensor may sense an external input generated by the user. The upper member UM may further include an adhesive layer to attach the anti-reflective layer to the input sensing sensor.

In the display device DD, the display panel DP may be disposed under (or below) the upper member UM. The lower member SP may be disposed under (or below) the display panel DP.

The display panel DP may include the display area AA through which the image IM is displayed and the non-display area NAA adjacent to the display area AA. For example, the front surface of the display panel DP may include the display area AA and the non-display area NAA. The display area AA may be activated in response to electrical signals and may be an area in which the image IM displayed through the active area AA-ED of the electronic device ED is generated.

The non-display area NAA may be defined adjacent to the display area AA. The non-display area NAA may surround the display area AA. A driving circuit or a driving line to drive the display area AA, various signal lines or pads to provide electrical signals to the display area AA, or electronic elements may be disposed in the non-display area NAA.

The electronic device ED may be provided with a through hole HH defined through at least one of components included therein. The through hole HH may be defined through, for example, each of the display panel DP, the upper member UM, and the lower member SP.

A first panel hole H1 may be defined in the display area AA of the display panel DP. The first panel hole H1 may be defined to overlap the sensing area SA-ED of the electronic device ED that may include the display panel DP. The first panel hole H1 may be defined through a portion of the display panel DP, which overlaps the sensing area SA-ED of the electronic device ED. For example, the first panel hole H1 may be formed to have a shape penetrating the display panel DP from an upper surface to a lower surface of the display panel DP, however, the disclosure should not be limited thereto or thereby. According to an embodiment, at least one component of the display panel DP may not be penetrated in the portion where the first panel hole H1 is defined. As an example, a base layer BL (refer to FIG. 10) of the display panel DP may not be penetrated in the portion where the first panel hole H1 is defined. The electro-optical module EOM may be disposed to correspond to the portion where the first panel hole H1 is defined. The first panel hole H1 may be formed since a deposition material is blocked by the plural first grooves HM1 (refer to FIG. 4) included in the second active area AR2 (refer to FIG. 3). The first panel hole H1 may correspond to the camera hole HO shown in FIG. 6.

A second panel hole H2 may be defined through the upper member UM to correspond to the first panel hole H1 of the display panel DP. The second panel hole H2 may be defined to overlap the sensing area SA-ED of the electronic device ED. FIG. 9 shows a structure in which the second panel hole H2 has substantially the same shape and size as those of the first panel hole H1 as a representative example, however, the disclosure should not be limited thereto or thereby. According to an embodiment, the shape and size of the second panel hole H2 may be different from those of the first panel hole H1.

The lower member SP may be disposed under (or below) the display panel DP. The lower member SP may support the display panel DP, may absorb impacts applied to the display panel DP, and may dissipate heat generated from components disposed under (or below) the display panel DP, for example, an electronic module EM and a power supply module PSM, which are described later.

A third panel hole H3 may have a shape penetrating the lower member SP from an upper surface to a lower surface of the lower member SP. FIG. 9 shows a structure in which the third panel hole H3 has substantially the same shape and size as those of the first panel hole H1 and the second panel hole H2, however, the disclosure should not be limited thereto or thereby. According to an embodiment, the shape and size of the third panel hole H3 may be different from those of the first panel hole H1 and the second panel hole H2.

The housing HU may accommodate the electro-optical module EOM, the power supply module PSM, the electronic module EM, and the display panel DP. The window WM may be coupled with or connected with the housing HU to form an exterior of the electronic device ED.

The electro-optical module EOM may overlap the sensing area SA-ED. The electro-optical module EOM may receive the external input through the sensing area SA-ED or may output signals through the sensing area SA-ED. The electro-optical module EOM may include a camera module r a sensor module.

The electronic module EM may include a control module, a wireless communication module, an image input module, an audio input module, an audio output module, a memory, and an external interface module. The electronic module EM may include a main circuit board, and the modules may be mounted on the main circuit board or may be electrically connected to the main circuit board via a flexible circuit board. The electronic module EM may be electrically connected to the power supply module PSM.

The power supply module PSM may supply a power required for the overall operation of the electronic device ED. The power supply module PSM may include a conventional battery device.

FIG. 10 is a schematic cross-sectional view of a portion of the display panel DP taken along line II-II′ of FIG. 9.

Referring to FIG. 10, the display panel DP may be a light emitting display panel. FIG. 10 shows a cross-section corresponding to one of pixels, for example, a cross-section corresponding to two transistors T1 and T2 and a light emitting element OLED.

The display panel DP may include the base layer BL, a circuit element layer ML disposed on the base layer BL, a display clement layer EL disposed on the circuit element layer ML, and an encapsulation layer TFE disposed on the display element layer EL.

The base layer BL may include a synthetic resin layer. The base layer BL may be formed by forming the synthetic resin layer on a support substrate used in case that the display panel DP is manufactured, forming a conductive layer and an insulating layer on the synthetic resin layer, and then, removing the support substrate.

The circuit element layer ML may include at least one insulating layer and a circuit element. The circuit element may include a signal line and a pixel driving circuit. An insulating layer, a semiconductor layer, and a conductive layer may be formed by a coating or depositing process. Then, the insulating layer, the semiconductor layer, and the conductive layer may be patterned by a photolithography process, and thus, the circuit element layer ML may be formed.

In the embodiment, the circuit element layer ML may include a buffer layer BFL, a barrier layer BRL, and first, second, third, fourth, fifth, sixth, and seventh insulating layers 10, 20, 30, 40, 50, 60, and 70. The buffer layer BFL, the barrier layer BRL, and the first, second, third, fourth, fifth, sixth, and seventh insulating layers 10, 20, 30, 40, 50, 60, and 70 may include one of an inorganic layer and an organic layer. The buffer layer BFL and the barrier layer BRL may include the inorganic layer. At least one of the fifth, sixth, and seventh insulating layers 50, 60, and 70 may include the organic layer.

FIG. 10 illustrates an arrangement relationship of a first active A1, a second active A2, a first gate G1, a second gate G2, a first source S1, a second source S2, a first drain D1, and a second drain D2 that form first and second transistors T1 and T2 as a representative example. In the embodiment, the first active A1 and the second active A2 may include different materials from each other. The first active A1 may include a polysilicon semiconductor material, and the second active A2 may include a metal oxide semiconductor material. The first source S1 and the first drain D1 may have a higher doping concentration than that of the first active A1 and may serve as an electrode. The second source S2 and the second drain D2 may correspond to an area in which the metal oxide semiconductor material is reduced and may serve as an electrode.

According to an embodiment, the first active A1 and the second active A2 may include substantially the same semiconductor material as each other, and in this case, a stack structure of the circuit element layer ML may be simplified.

The display element layer EL may include a pixel definition layer PDL and the light emitting element OLED. The light emitting element OLED may be an organic light emitting diode or a quantum dot light emitting diode. An anode AE may be disposed on the seventh insulating layer 70. At least a portion of the anode AE may be exposed through a pixel opening PDL-OP of the pixel definition layer PDL. The pixel opening PDL-OP of the pixel definition layer PDL may define a light emitting area PXA. A non-light-emitting area NPXA may surround the light emitting area PXA.

A hole control layer HCL and an electron control layer ECL may be commonly disposed in the light emitting area PXA and the non-light-emitting area NPXA. The light emitting layer EML may include a light emitting material and may be formed in a pattern shape to correspond to the pixel opening PDL-OP. The light emitting layer EML may be deposited in a different way from the hole control layer HCL and the electron control layer ECL, each having a film shape. As an example, the hole control layer HCL and the electron control layer ECL may be commonly formed in the pixels using an open mask. The light emitting layer EML may be formed in a pattern shape to correspond to the pixel opening PDL-OP using the mask assembly according to the disclosure. In detail, a deposition pattern may be formed to correspond to each of the holes HL included in the first active area AR1 shown in FIG. 4, and the deposition pattern may be the light emitting layer EML of the display panel DP, however, the disclosure should not be limited thereto or thereby. According to an embodiment, similar to the light emitting layer EML, the hole control layer HCL and the electron control layer ECL may also be formed in a pattern shape to correspond to the pixel opening PDL-OP using the mask assembly according to the disclosure.

A cathode CE may be disposed on the electron control layer ECL. The encapsulation layer TFE may be disposed on the cathode CE. The encapsulation layer TFE may be a thin film encapsulation layer to encapsulate the display clement layer EL. The encapsulation layer TFE may include a plurality of thin layers. The thin layers may include an inorganic layer and an organic layer. The encapsulation layer TFE may include an insulating layer to encapsulate the display clement layer EL and a plurality of insulating layers to improve a light emitting efficiency.

Hereinafter, the embodiment will be described with reference to detailed characteristics data of the mask assembly of the embodiment example and a mask assembly of a comparative example. The embodiment described below is an example to help in an understanding of the disclosure, and the scope of the disclosure should not be limited thereto.

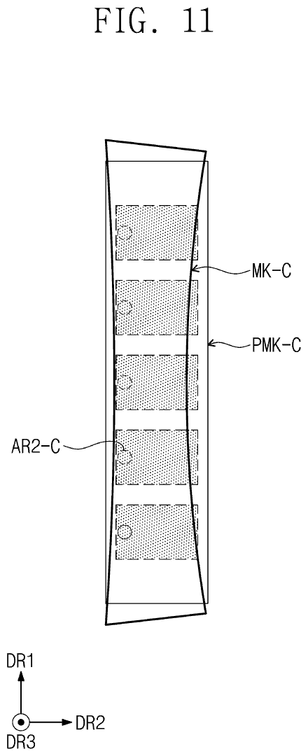

FIG. 11 is a schematic plan view showing a variation in shape of a mask according to the comparative example. In FIG. 11, the mask of the comparative example before the shape change of the mask is referred to as a preliminary comparative mask PMK-C and the mask of the comparative example after the shape change of the mask is referred to as a comparative mask MK-C. The shape of the comparative mask MK-C is briefly illustrated in order to clearly show the change of the shape.

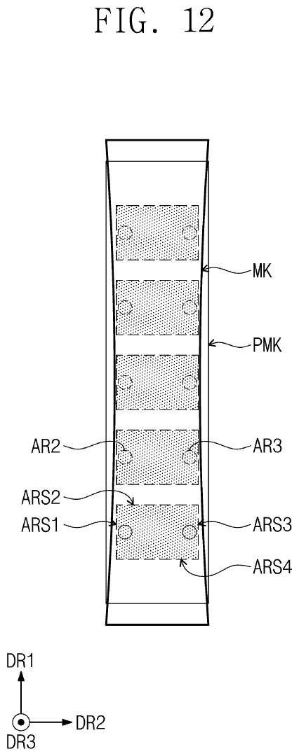

FIG. 12 is a schematic plan view showing a variation in shape of a mask according to an embodiment. In FIG. 12, the mask of the embodiment before the shape change of the mask is referred to as a preliminary mask PMK and the mask of the embodiment after the shape change of the mask is referred to as the mask MK. The shape of the mask MK is briefly illustrated in order to clearly show the change of the shape. The mask MK shown in FIG. 12 is the mask MK shown in FIG. 1. The mask MK shown in FIG. 1 is illustrated as having a rectangular shape and may have substantially the same shape as the mask MK shown in FIG. 12. The comparative mask MK-C may be substantially the same as the mask shown in FIG. 1 except that the comparative mask MK-C does not include the first-second active area AR1-2 and the third active area AR3. The comparative mask MK-C may include a second comparative active area AR2-C that is substantially the same as the second active area AR2 of the mask MK of FIG. 1. Details of the same elements described with reference to FIG. 1 will not be repeated.

The comparative mask MK-C and the mask MK are manufactured of invar and have substantially the same thickness of about 20 μm. Experiments were performed to determine the occurrence of bending in case that each of the comparative mask MK-C and the mask MK is pulled and stretched in the first direction DR1 and a direction opposite to the first direction DR1 to allow a width in the first direction DR1 thereof to increase by about 0.02%. In case that a mask is stretched, a width in the second direction DR2 of an area of the mask may be reduced. The occurrence of bending in the mask means that the width of the mask in the second direction DR2 is asymmetrically reduced and the mask is left and right asymmetrical. As an example, in a case where one long side adjacent to the second comparative active area AR2-C of the preliminary comparative mask PMK-C is concavely deformed in the second direction DR2 and the other long side opposite to the one long side is more concavely deformed in a direction opposite to the second direction DR2 than a degree of deformation of the one long side adjacent to the second comparative active area AR2-C, the preliminary comparative mask PMK-C is bent in the second direction DR2 as a whole. The symmetrical decrease in the width of the preliminary mask PMK means that a deformation degree in the second direction DR2 of one long side adjacent to the second active area AR2 of the preliminary mask PMK may be the same as or may be substantially the same as a deformation degree of the other long side opposite to the one long side in the direction opposite to the second direction DR2. The deformation of the one long side in the second direction DR2 means that a portion of the one long side is concavely deformed in the second direction DR2. The deformation of the other long side in the direction opposite to the second direction DR2 means that a portion of the other long side is concavely deformed in the direction opposite to the second direction DR2. In case that the one long side is deformed in the second direction DR2 or the other long side is deformed in the direction opposite to the second direction DR2, the width in the second direction DR2 of the preliminary mask PMK is reduced.

Referring to FIG. 11, in case that the tensile force is applied to the preliminary comparative mask PMK-C in the first direction DR1 and the direction opposite to the first direction DR1, the degree of deformation of the one long side that is adjacent to the second comparative active area AR2-C and is concavely deformed in the second direction DR2 is greater than the degree of deformation of the other long side that is opposite to the one long side and is concavely deformed in the direction opposite to the second direction DR2. Since the comparative mask MK-C does not include an area corresponding to the third active area AR3 of the mask MK, the comparative mask MK-C has an asymmetrical shape and the tensile force is not uniformly applied. As a result, the comparative mask MK-C has a shape bent in the second direction DR2 as a whole.

Referring to FIG. 12, in case that the tensile force is applied to the preliminary mask PMK in the first direction DR1 and the direction opposite to the first direction DR1, the degree of deformation of the one long side that is adjacent to the second active area AR2 and is concavely deformed in the second direction DR2 is substantially the same as the degree of deformation of the other long side that is opposite to the one long side and is concavely deformed in the direction opposite to the second direction DR2. Different from the comparative mask MK-C, the mask MK may include both the second active area AR2 and the third active area AR3 and has a bilaterally symmetrical shape. Accordingly, the tensile force is uniformly applied, and thus, the mask MK is not bent in the second direction DR2 or the direction opposite to the second direction DR2.

Hereinafter, the embodiment will be described with reference to detailed characteristics data of the mask assembly of the embodiment example and the mask assembly of the comparative example. The embodiment described below is an example to help in an understanding of the disclosure, and the scope of the disclosure should not be limited thereto.

In the following descriptions, the deformation of the one long side adjacent to the second active area or the second comparative active area in the second direction is indicated by positive (+), and the deformation of the other long side opposite to the one long side in the direction opposite to the second direction is indicated by negative (−). The deformation degree of a long side is represented by a maximum variation value, which is defined as a maximum distance from the long side before the tensile force is applied to the long side after the tensile force is applied.

The degree of bending is defined as a difference in absolute value between a maximum variation value of the one long side and a maximum variation value of the other long side. In the case where the width in the second direction of the mask is symmetrically reduced in case that the mask is tensioned, it may be understood that the bending phenomenon of the mask is improved.

The variation of the one long side adjacent to the second comparative active area of the comparative mask is equal to or greater than about +0.7766 μm and equal to or smaller than about +6.800 μm, the variation of the other long side opposite to the one long side of the comparative mask is equal to or greater than about −0.4280 μm and equal to or smaller than about −7.656 μm, and the bending degree is about 0.856 μm. On the other hand, the variation of the one long side of the mask of the embodiment example is equal to or greater than about +1.164 μm and equal to or smaller than about +6.985 μm, the variation of the other long side is equal to or greater than about −1.164 μm and equal or smaller than about −6.985 μm, and the bending degree is about 0 μm. The deformation degree of the one long side adjacent to the second comparative active area of the comparative mask is about 6.0234 μm, the deformation degree of the other long side opposite to the one long side of the comparative mask is about 7.228 μm, the deformation degree of the one long side adjacent to second active area of the mask of the embodiment example is about 5.821 μm, and the deformation degree of the other long side opposite to the one long side of the mask of the embodiment example is about 5.821 μm. The reason why the deformation degree of the long side of the mask has a lower value than the deformation degree of the long side of the mask of the comparative example is that the mask of the embodiment example may include the third active area symmetrical to the second active area, the mask is deformed symmetrically, and the degree of deformation is small. The bending degree of the comparative mask is about 0.856 μm, and the bending degree of the mask of the embodiment example is about 0 μm. This means that the mask of the embodiment example is symmetrically deformed compared with the mask of the comparative example. In case that comparing with the mask of the comparative example, it is observed that the bending phenomenon of the mask of the embodiment example, which occurs in case that the tensile force is applied to the mask, is improved.

Although embodiments have been described, it is understood that the disclosure should not be limited to these embodiments but various changes and modifications can be made by one of ordinary skill in the art within the spirit and scope of the disclosure and as hereinafter claimed. Therefore, the disclosed subject matter should not be limited to any single embodiment described herein, and the scope of the disclosure shall be determined according to the attached claims.

What is claimed is:

1. A mask assembly comprising:
a frame including a frame opening;
a first stick disposed on the frame, the first stick overlapping the frame opening in a plan view and extending in a first direction; and
a mask disposed on the first stick, wherein
the mask comprises a plurality of active areas and an inactive area, each of the plurality of active areas comprises:
a first active area including a plurality of holes;
a second active area including a plurality of first grooves; and
a third active area including a plurality of second grooves,
the third active area overlaps the second active area in a second direction intersecting the first direction, and
the first stick overlaps the third active area in the plan view.

2. The mask assembly of claim 1, wherein a width in a third direction intersecting the first direction and the second direction of each of the plurality of holes is greater than a width in the third direction of each of the plurality of first grooves and the plurality of second grooves.

3. The mask assembly of claim 2, wherein a width in the third direction of each of the plurality of first grooves and the plurality of second grooves is equal to or greater than about 40% and equal to or less than about 60% of the width in the third direction of each of the plurality of holes.

4. The mask assembly of claim 1, wherein
each of the plurality of active areas has a substantially rectangular shape, and
the active areas are disposed in the first direction.

5. The mask assembly of claim 4, wherein
each of the plurality of active areas comprises:
a first side parallel to the first direction; and
a second side parallel to the second direction, and
the first side has a length less than a length of the second side.

6. The mask assembly of claim 4, wherein
each of the plurality of active areas comprises:
a first side parallel to the first direction; and
a second side parallel to the second direction, and
the first side has a length greater than a length of the second side.

7. The mask assembly of claim 4, wherein
each of the plurality of active areas comprises:
a first side parallel to the first direction;
a third side parallel to the first direction and opposite to the first side;
a second side parallel to the second direction; and
a fourth side parallel to the second direction and opposite to the second side,
the second active area is disposed adjacent to the first side, and
the third active area is disposed adjacent to the third side.

8. The mask assembly of claim 7, wherein
the first active area comprises a first-first active area comprising the first side and a first-second active area comprising the third side, and
the first stick overlaps the first-second active area in the plan view.

9. The mask assembly of claim 8, wherein the first stick does not overlap the second active area in the plan view.

10. The mask assembly of claim 1, further comprising:
a second stick disposed between the frame and the mask, the second stick extending in the second direction.

11. The mask assembly of claim 10, wherein
the mask includes a plurality of masks,
the first stick includes a plurality of first sticks,
the second stick includes a plurality of second sticks,
the plurality of second sticks are disposed in the first direction,
the plurality of first sticks are disposed in the second direction, and
the plurality of masks are disposed in the second direction.

12. The mask assembly of claim 10, wherein a width in the first direction of the second stick is less than a width between two adjacent active areas among the plurality of active areas.

13. The mask assembly of claim 10, wherein a width in the second direction of the first stick is greater than a width in the second direction of the third active area.

14. The mask assembly of claim 10, wherein
The mask comprises a magnetic material, and
the first stick and the second stick comprise a non-magnetic material.

15. The mask assembly of claim 10, wherein
The mask comprises invar, and
the first stick and the second stick comprise aluminum.

16. A method of manufacturing a display panel, comprising:
providing a substrate;
placing a mask assembly on the substrate; and
depositing an organic material on the mask to form a pattern, the mask assembly comprising:
a frame including a frame opening;
a first stick disposed on the frame, the first stick overlapping the frame opening in a plan view and extending in a first direction; and
a mask disposed on the first stick, wherein
the mask comprises a plurality of active areas and an inactive area,
each of the plurality of active areas comprises:
a first active area including a plurality of holes;
a second active area including a plurality of first grooves; and
a third active area including a plurality of second grooves,
the third active area overlaps the second active area in a second direction intersecting the first direction, and
the first stick overlaps the third active area in the plan view.

17. The method of claim 16, wherein
the organic material comprises a light emitting material, and
the pattern comprises a light emitting layer.

18. The method of claim 16, wherein a width in a third direction intersecting the first direction and the second direction of each of the plurality of holes is greater than a width in the third direction of each of the plurality of first grooves and the plurality of second grooves.

19. The method of claim 16, wherein a width in the first direction of the mask is greater than a width in the first direction of the frame opening.

20. The method of claim 19, wherein
the mask comprises a welding portion that does not overlap the frame opening in a plan view, and
the welding portion is welded to the frame.
